(19) United States
(12) Patent Application Publication
(10) Pub. No.: US 2015/0003010 A1
(43) Pub. Date: Jan. 1, 2015

(54) PRESSURE-ACTIVATED SERVER COOLING SYSTEM

(71) Applicant: Silicon Graphics International Corp., Milpitas, CA (US)

(72) Inventor: Robert Michael Kinstle, III, Livermore, CA (US)

(73) Assignee: Silicon Graphics International Corp., Milpitas, CA (US)

(21) Appl. No.: 14/289,590

(22) Filed: May 28, 2014

Related U.S. Application Data
(60) Provisional application No. 61/841,270, filed on Jun. 28, 2013.

(51) Int. Cl. H05K 7/20

(52) U.S. Cl. CPC H05K 7/20736
USPC 361/679.49

(57) ABSTRACT

A pressure-activated server cooling system includes a server rack that houses one or more servers. The server rack has an interior plenum. A fan is coupled to the server rack that exhausts air from inside the plenum to outside the server rack. A differential pressure sensor collects pressure sensor data and a fan controller, which is operatively connected to the fan and the differential pressure sensor, activates the fan in response to the pressure sensor data. In some embodiments, the fan controller increases the speed of the fan when the pressure sensor data indicates greater than atmospheric pressure in the plenum.

### CROSS-REFERENCE TO RELATED APPLICATIONS

The present application claims the priority benefit of U.S. provisional application No. 61/841,270 filed Jun. 28, 2013, the disclosure of which is incorporated herein by reference.

### BACKGROUND OF THE INVENTION

1. Field of the Invention

This disclosure relates to servers. More specifically, it relates to pressure-activated server cooling systems.

2. Description of the Related Art

As companies create and process more and more data, the servers required to handle the data must provide faster access and higher storage capacities. As server processing power continues to increase, so does the heat that is radiated from server processors and other internal circuitry. Battling overheating problems has become a commonplace activity amongst server manufacturers and data management companies.

Servers are typically housed in tray or blade chasses. Several servers are usually stored together within a single “server rack.” Most modern data management companies rely on air cooling systems to keep servers from overheating. Such systems often include a “server fan” within each server and large “rack fans” located behind the servers within the server rack. Each rack fans overlaps multiple servers because using a single rack fan for each individual server requires impractical amounts of power that data management companies and their customers are unwilling to tolerate. The server fan within each server draws cool air through an inlet in the front of the server and exhausts hot air out its rear. Although server racks are equipped with rear vents or outlets, they are insufficient to passively mitigate the build up of heat and pressure within the rack.

Rack fans supplement the server fans by attempting to evacuate hot air from the server rack. Although a server motherboard can control the speed of its onboard server fan, it cannot control the rack fans. The rack fans must be controlled independently. When the rack fans fail to exhaust hot air from the server rack fast enough, the build up of heat and pressure causes the servers stored inside to overheat. Many modern server racks feature complicated components and cabling running along the rear of the server. Such components often partially block outlet vents and in doing so further impede the ability of the system to evacuate hot air and pressure from the server rack.

Previous attempts to solve this issue have proven inefficient, imprecise, and unattractive to customers in the data management market. One solution involves constantly running rack fans to ensure that heat is always sufficiently ventilated from the server rack. This solution presents a number of negative side effects including over-consumption of energy and markedly detrimental effects on server cooling efficiencies. Thermodynamic principles known in the art dictate that the efficiency with which a server is cooled is maximized when the difference between the cold and hot air on opposite ends of a server is highest. This difference in temperature is commonly referred to in the art as “Delta T” or “ΔT.”

Previously attempted solutions that leave rack fans constantly running at the same speed not only waste energy by incorrectly assuming that servers are always running hot, but also pull more air through the server rack than the server itself is trying to control using its internal server fan. In doing so, such solutions fail to precisely exhaust the hot air while leaving behind cool air that would otherwise contribute to the sort of high ΔT rating that customers in the data management industry not only find desirable but are now demanding at an increasing rate.

Another attempted solution s involves automatically adjusting the speed of the fans using temperature sensors. A temperature sensor is placed within the server rack near the servers. When the temperature in the server rack exceeds a certain threshold indicating that one or more servers are overheating, the system automatically increases the speed of the rack fans. Those solutions, too, are riddled with shortcomings. As noted above, servers are usually stored as trays or blades that slide into the server rack. As a result, servers are housed in close proximity to one another. In such configurations, temperature-based automated cooling systems can be especially imprecise.

For example, in one common scenario, server A is running hot while server B, which is located directly adjacent to server A, is running cold because it has not been processing as much data as server A. The hot air exhausted from server A mixes with the nearby cooler air exhausted from server B to produce moderately warm air. The temperature sensor then detects the moderately warm air temperature and automatically adjusts the rack fans to cool a moderately heated server, notwithstanding that server A is actually running hot and needs additional cooling and server B is relatively cool and needs no additional cooling. The result is that server A ultimately overheats while energy is wasted cooling server B when server B was already sufficiently cool in the first place.

Moreover, as noted above, such systems also pull cool air through servers and into the space behind the server rack that, in order to maximize cooling efficiencies, should be filled with exhausted hot air. In doing so, such solutions lower the ΔT rating of the system and ultimately make it undesirable if not unacceptable to savvy customers in the modern data management industry. Moreover, cooling systems that depend on temperature readings can only be optimized for a single ambient temperature. As a result, an entire room full of servers may be forced to operate in less than optimal ambient temperature conditions that are maintained as a compromise across multiple servers that each have their own optimal operating conditions.

Given these shortcomings, there is a need in the art for a temperature-independent server cooling system that results in more precise and efficient cooling operations.

### SUMMARY

The pressure-activated server cooling system disclosed herein automatically mitigates detrimental flow impedances that naturally build up in modern server racks and ultimately cause servers to overheat. The system does so by detecting and responding to the presence of excess air pressure in the space adjacent to the server outlet vents but still inside the rack doors and EMI barriers. The system reduces the pressure in a controlled fashion that allows for energy efficient cooling and does not depend on error-prone temperature readings. Because the system is controlled, it also avoids drawing excess cool air through the servers that would otherwise drop the ΔT rating of the system to a level that customers may deem unacceptable. Moreover, because the system is pressure-activated and does not depend on temperature readings, it can be optimized regardless of the ambient temperature present at any given time. By reducing the threat of overheating caused by flow impedances within server racks, the system may also allow data management companies to add additional components to racks that they might otherwise avoid adding due to concerns that the components may further impede air flow.

In one embodiment, the system may include a server rack that houses one or more servers and has an interior plenum. A fan may be coupled to the server rack that exhausts air from inside the plenum to outside the server rack. A differential pressure sensor may collect pressure sensor data. A fan controller, which may be operatively connected to the fan and the differential pressure sensor, may activate the fan in response to the pressure sensor data. In various embodiments, the fan controller may activate and/or increase the speed of the fan when the pressure sensor data indicates that the pressure in the plenum is greater than atmospheric or ambient pressure.

In another embodiment, a temperature-independent method for cooling a server likewise automatically overcomes flow impedances in server racks by detecting and reducing excess pressure within the server rack. The method may include providing a server rack that houses one or more servers and includes an interior plenum. After the one or more servers are powered on, the ambient air pressure outside the server rack may be detected. The air pressure within the plenum of the server rack may be detected. The ambient air pressure may be compared to the air pressure within the plenum and the air pressure within the plenum may be automatically reduced when the air pressure within the plenum is greater than the ambient air pressure. The method may be implemented either with or without fans and, depending on the embodiment. This method allows the servers themselves to manage their own internal fans to provide sufficient cooling on a per server basis, and the rack fans to provide bulk flow on an aggregate basis.

### BRIEF DESCRIPTION OF DRAWINGS

FIG. 1 is a side view of an exemplary pressure-activated server cooling system in accordance with the present disclosure.

FIG. 2 is a flow diagram of an exemplary temperature-independent method for cooling a server rack in accordance with the present disclosure.

FIG. 3 is a flow diagram of another exemplary temperature-independent method for cooling a server rack in accordance with the present disclosure.

### DETAILED DESCRIPTION

A pressure-activated server cooling system is provided. The system automatically mitigates flow impedances that naturally build up in server racks. The system does so by detecting and responding to the presence of excess air pressure in the space adjacent to the server outlet vents. The system reduces the pressure in a controlled fashion that allows for energy efficient cooling that does not depend on error-prone temperature readings. Because it is controlled, the system also avoids drawing excess cool air through the servers that would otherwise drop the ΔT rating of the system to a level that customers may deem unacceptable.

Additionally, because the system is pressure-activated and does not depend on temperature readings, it can be optimized regardless of the ambient temperature present at any given time. By reducing the threat of overheating caused by flow impedances within server racks, the system may also allow data management companies to add more components to the racks than traditional air cooling would allow.

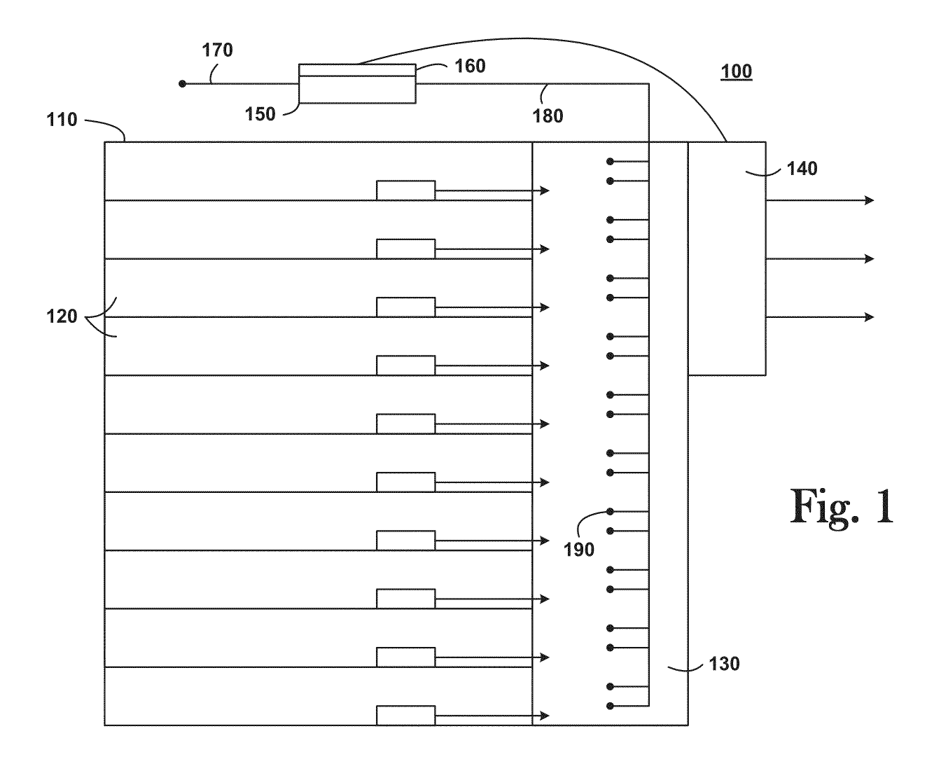

A temperature-independent method for cooling a server is also provided. The method includes detecting and reducing excess pressure in the space adjacent to the server outlet vents within a server rack. As described below in greater detail, the method may be implemented either with or without fans and, depending on the embodiment, may include comparing plenum pressure to ambient atmospheric pressure. FIG. 1 shows a side view of an exemplary pressure-activated server cooling system.

A pressure-activated server cooling system 100 may include a server rack 110 that houses one or more servers 120. Servers 120 may be configured in any number of presently known or yet to be developed chassis configurations, such as a tray or blade. Server rack 110 may include an internal plenum 130. As used herein, the term “plenum” refers to any chamber within the interior of a server rack that is filled with air, including a chamber that has one or more outlets through which air may pass between the chamber and the ambient air outside the chamber.

Pressure-activated server cooling system 100 may further include a fan 140 coupled to server rack 110 that exhausts air from inside plenum 130 to outside server rack 110. Fan 140 may be a single large fan, or it may include multiple fans working together. For example, in one embodiment, fan 140 may be a row of 120 mm fans disposed down the back of server rack 110. In any given embodiment, the optimal composition, size, speed, and power requirements of fan 140 will depend on various considerations related to the overall server design, such as the size and construction of server rack 110, the quantity of and amount of heated generated by servers 120, considerations relating to how much space is available at the back of server rack 110, and many other design considerations that will be readily recognized by persons of ordinary skill in the art.

In some embodiments, fan 140 may be disposed within plenum 130, while in other embodiments fan 140 may be disposed outside plenum 130 or completely outside server rack 110 altogether. As shown in FIG. 1, fan 140 is disposed outside server rack 110. In still other embodiments, fan 140 may be disposed within other interior regions of server rack 110, so long as fan 140 can sufficiently evacuate air from within server rack 110. In any given embodiment, the location of fan 140 will depend on the design considerations discussed above in addition to the amount of space available in plenum 130 or server rack 110, where applicable.

Pressure-activated server cooling system 100 may include a differential pressure sensor 150 that collects pressure sensor data. As used herein, the term “differential pressure sensor” includes any type of pressure sensor, including pressure sensors in which one side is open to the ambient air pressure, atmospheric pressure, or some other fixed pressure. Moreover, as used herein, the term “pressure sensor” includes but is not limited to pressure transducers, pressure transmitters, pressure senders, pressure indicators, piezometers, manometers, and other pressure detecting devices known in the art and readily recognized as suitable by persons of ordinary skill in the art.

In one embodiment, the pressure sensor data may include a value corresponding to the pressure differential between the ambient air outside server rack 110 and the air within plenum 130. In some embodiments, differential pressure sensor 150 may measure the pressure differential by: measuring a first air pressure through a first tube 170 communicatively coupled to the ambient air outside server rack 110, measuring a second air pressure through a second tube 180 communicatively coupled to plenum 130 of server rack 110, and comparing the first air pressure to the second air pressure.

In some embodiments, either or both of first tube 170 and second tube 180 may include a single opening, while in other embodiments either or both tubes 170 and 180 may branch into multiple sub-tubes as shown in FIG. 1 with respect to second tube 180. In some embodiments, depending on various design considerations related to the dimension and contents of server rack 100, having one or both of first tube 170 or second tube 180 branch into multiple sub-tubes may prove beneficial for generating more accurate pressure sensor data.

For example, in embodiments featuring multiple sub-tubes as opposed to a single tube, the differential pressure sensor 150 may receive air from multiple regions within the plenum and may then take an average to determine the overall plenum pressure. Having multiple sub-tubes may also allow for increased accuracy because each server 120 within server rack 110 may be located close to one or several of the data collection inputs, i.e., sub-tubes, of differential pressure sensor 150. For example, each server 120 may be located adjacent to three or four data collection inputs. In some embodiments, the distal openings of the first and second tubes may be covered by a piece of open-cell foam 190. Open-cell foam 190 may allow air to pass into tubes 170 and 180 while preventing the flow of air across the inlet from causing a suction effect that could otherwise introduce errors into the pressure sensor data.

Although embodiments disclosed herein refer to ambient air pressure for illustrative purposes, differential pressure sensor 150 may compare the first air pressure in plenum 130 to either the ambient or atmospheric air pressure outside of server rack 110.

Pressure-activated server cooling system 100 may further include a fan controller 160 that is operatively connected to fan 140 and differential pressure sensor 150. As shown in FIG. 1, in some embodiments, differential pressure sensor 150 may be integrated into fan controller 160. Fan controller 160 may include a microcontroller, fan drivers, and other components necessary for its operation. The optimal specifications for fan controller 160 in any given embodiment will depend on various design requirements related to the remainder of the system, including the quantity, size, and power requirements of fan 140.

Fan controller 160 may activate fan 140 in response to the pressure sensor data collected by differential pressure sensor 150. Fan controller 160 may also adjust the speed of fan 140 based on the pressure sensor data. For example, in some embodiments, fan controller 160 may increase the speed of fan 140 when the pressure sensor data collected by differential pressure sensor 150 indicates greater than atmospheric or ambient air pressure in plenum 130. Fan controller 160 may do so by transmitting a signal to fan 140 that is associated with greater than atmospheric or ambient air pressure in plenum 130. Fan controller 160 may transmit the signal to fan 140 wirelessly or through a wired connection, such as by sending a standard pulse-width modulation (PWM) signal to fan 140.

In embodiments in which pressure sensor data includes a pressure differential value, fan controller 160 may activate and/or increase the speed of fan 140 in response to receiving a signal from differential pressure sensor 150 indicating that the pressure differential is positive. In such embodiments, fan controller 160 may also decrease the speed of fan 140 when the pressure sensor data collected by differential pressure sensor 150 indicates a zero or negative pressure differential in plenum 130.

In operation, when differential pressure sensor 150 detects excess pressure in plenum 130, which may be defined as greater than atmospheric pressure or ambient pressure, or some other equivalent pressure, fan controller 160 may send a signal to fan 140 to activate and/or increase the speed of fan 140. Fan 140 may then speed up to exhaust the excess air from plenum 130. In doing so, fan 140 may successfully reduce the air pressure in plenum 130. Differential pressure sensor 150 may continue to collect pressure sensor data as the pressure in plenum 130 decreases. When the pressure in plenum 130 has dropped such that differential pressure sensor 150 detects a zero or negative pressure within the pressure sensor data, fan controller 160 may send a signal to fan 140 to reduce its speed. In some embodiments, fan controller 160 may deactivate fan 140 altogether when the pressure sensor data indicates sufficiently decreased pressure in plenum 130. In either instance, fan controller 160 may do so by transmitting a signal to fan 140 that is associated with a plenum pressure that is less than atmospheric or ambient, pressure.

In embodiments in which differential pressure sensor 150 measures the pressure differential by measuring and comparing a first and second air pressure through first tube 170 and second tube 180, respectively, fan controller 160 may activate fan 140 in response to receiving a signal from differential pressure sensor 150 indicating that the second air pressure is greater than the first air pressure. Similarly, fan controller 160 may increase the speed of fan 140 in response to receiving a signal from differential pressure sensor 150 indicating that the second air pressure is greater than the first air pressure. Fan controller 160 may also decrease the speed of fan 140 in response to receiving a signal from differential pressure sensor 150 indicating that the second air pressure is less than the first air pressure. In some embodiments, fan controller 160 may deactivate fan 140 in response to receiving a signal from differential pressure sensor 150 indicating that the second air pressure is less than the first air pressure.

Reducing or fully deactivating fan 140 after the flow impedance in plenum 130 has been sufficiently overcome allows for increased energy savings and better preservation of desirable AT ratings. Specifically, in such cases fan 140 avoids utilizing unnecessary power to exhaust air out of plenum 130 in times when plenum 130 is no longer hindered by flow impedances caused by excess pressure. System 100 also preserves desirable AT ratings by only evacuating as much excess air from plenum 130 as is necessary to overcome flow impedances that would otherwise cause servers 120 to overheat. Because system 100 operates fan 140 in a controlled fashion, it avoids drawing cool air through servers that are already running cool and ultimately lowering the AT rating of the system.

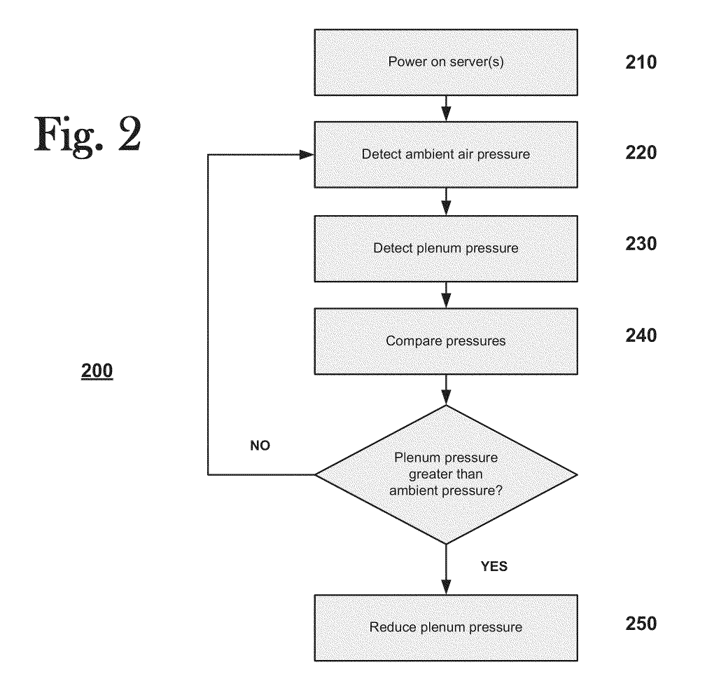

FIG. 2 is a flow chart depicting an exemplary method for cooling a server rack. Exemplary method 200 may include providing a server rack such as server rack 110 of FIG. 1. The server rack may include a plenum and may house one or more servers. Method 200 may include a step 210 of powering on the one or more servers. Method 200 may further include a step 220 of detecting the ambient air pressure outside the server rack. Method 200 may also include a step 230 of detecting the air pressure within the plenum of the server rack, and a step 240 of comparing the ambient air pressure to the air pressure within the plenum. In some embodiments, steps 220, 230, and 240 may be achieved using a differential pressure sensor. For example, in another embodiment, the method may include determining the pressure differential between the ambient air pressure outside the server rack and the air pressure within the plenum of the server rack, and then reducing the air pressure within the plenum when pressure differential is positive.

In other embodiments, other devices for detecting pressure may be utilized, such as manual pressure gauge.

At step 250, method 200 may include reducing the air pressure within the plenum when the air pressure within the plenum is greater than the ambient air pressure. In doing so, method 200 may reduce the air pressure within the plenum in an amount that is very close to the pressure increase resulting from the sum total air forced into the plenum by the server fans located within the servers.

In one embodiment, the step of reducing the air pressure within the plenum may be accomplished using fans. In other embodiments, other devices or principles for reducing the pressure within the plenum may be utilized, including those that do not involve or contain fans. As noted above, reducing the excess air pressure within the plenum mitigates the flow resistance that would otherwise trap heat within the server rack and cause the servers to overheat. By not relying on temperature measurements, the method avoids errors introduced when air streams being exhausted from two adjacent servers by their internal server fans bear two very different temperatures. Although embodiments disclosed herein refer to ambient air pressure for illustrative purposes, other embodiments of method 200 may including comparing the first air pressure in plenum 130 to the ambient or atmospheric air pressure outside of server rack.

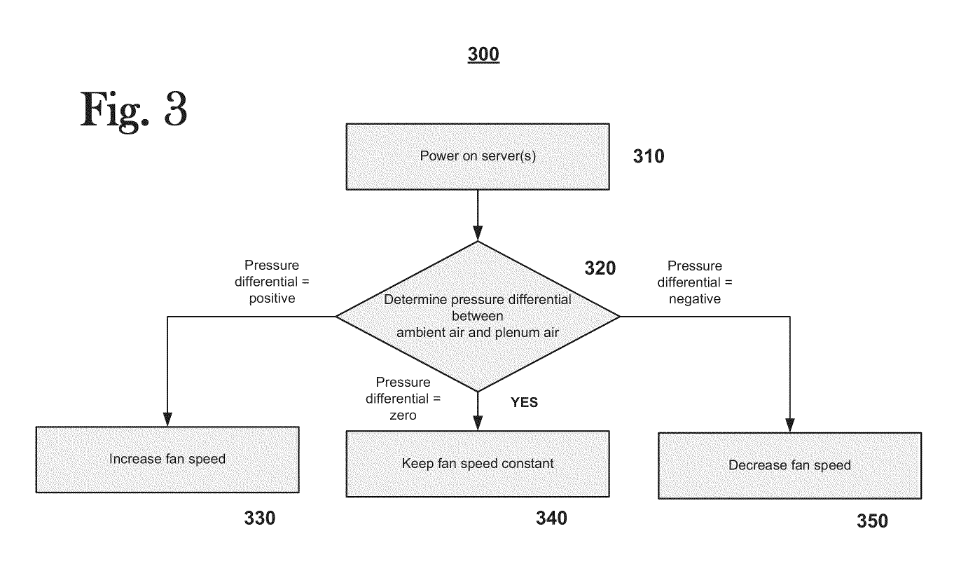

FIG. 3 is a flow diagram of another exemplary temperature-independent method for cooling a server rack in accordance with the present disclosure. Exemplary method 300 may include providing a server rack such as server rack 110 of FIG. 1. The server rack may include a plenum and may house one or more servers. Method 300 may include a step 310 of powering on the one or more servers. Method 300 may further include a step 320 of determining the pressure differential between the ambient air pressure and the air pressure in the plenum of the server rack. Method 300 may include a step 330 of increasing the fan speed to reduce the pressure in the plenum if the pressure differential is positive. Method 300 may also include a step 340 of keeping the fan speed constant if the pressure differential is zero. The ultimate goal of method 300 is to maintain a zero pressure differential. To that end, method 300 may further include a step 350 of decreasing the fan speed when the pressure differential is negative.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A pressure-activated server cooling system, comprising:
a server rack that houses one or more servers, an interior of the server rack including a plenum;
a fan coupled to the server rack that exhausts air from inside the plenum to outside the server rack;
a differential pressure sensor that collects pressure sensor data; and
a fan controller operatively connected to the fan and the differential pressure sensor that activates the fan in response to the pressure sensor data.

2. The pressure-activated server cooling system of claim 1, wherein the fan controller further adjusts the speed of the fan based on the pressure sensor data.

3. The pressure-activated server cooling system of claim 2, wherein the fan controller increases the speed of the fan when the pressure sensor data indicates greater than atmospheric pressure in the plenum by transmitting to the fan a signal associated with greater than atmospheric pressure in the plenum.

4. The pressure-activated server cooling system of claim 2, wherein the fan controller decreases the speed of the fan when the pressure sensor data indicates less than atmospheric pressure in the plenum by transmitting to the fan a signal associated with less than atmospheric pressure in the plenum.

5. The pressure-activated server cooling system of claim 2, wherein the fan controller deactivates the fan when the pressure sensor data indicates less than atmospheric pressure in the plenum by transmitting to the fan a signal associated with less than atmospheric pressure in the plenum.

6. The pressure-activated server cooling system of claim 1, wherein the pressure sensor data includes a pressure differential between the ambient air outside the server rack and the air within the plenum of the server rack.

7. The pressure-activated server cooling system of claim 6, wherein the pressure differential is positive.

8. The pressure-activated server cooling system of claim 6, wherein the differential pressure sensor measures the pressure differential by measuring a first air pressure through a first tube communicatively coupled to the ambient air outside the server rack, and measuring a second air pressure through a second tube communicatively coupled to the plenum of the server rack; and comparing the first air pressure to the second air pressure.

9. The pressure-activated server cooling system of claim 8, wherein the fan controller activates the fan after receiving a signal from the differential pressure sensor indicating that the second air pressure is greater than the first air pressure.

10. The pressure-activated server cooling system of claim 8, wherein the fan controller increases the speed of the fan after receiving a signal from the differential pressure sensor indicating that the second air pressure is greater than the first air pressure.

11. The pressure-activated server cooling system of claim 8, wherein the fan controller decreases the speed of the fan after receiving a signal from the differential pressure sensor indicating that the second air pressure is less than the first air pressure.

12. The pressure-activated server cooling system of claim 8, wherein the fan controller deactivates the fan after receiving a signal from the differential pressure sensor indicating that the second air pressure is less than the first air pressure.

13. The pressure-activated server cooling system of claim 1, wherein the fan is disposed within the plenum of the server rack.

14. The pressure-activated server cooling system of claim 1, wherein the fan is disposed outside the server rack.

15. The pressure-activated server cooling system of claim 8, wherein the distal openings of the first and second tubes are covered by a piece of open-cell foam.

16. The pressure-activated server cooling system of claim 1, wherein the system includes a plurality of digital signals.

17. The pressure-activated server cooling system of claim 1, wherein the system includes a plurality of analog signals.

18. The pressure-activated server cooling system of claim 1, wherein the system includes a plurality of digital and analog signals.

19. A temperature-independent method for cooling a server rack, comprising:
providing a server rack, the server rack including a plenum and housing one or more servers;
powering on the one or more servers;
detecting the ambient air pressure outside the server rack;
detecting the air pressure within the plenum of the server rack;
comparing the ambient air pressure to the air pressure within the plenum; and
reducing the air pressure within the plenum when the air pressure within the plenum is greater than the ambient air pressure.

20. A temperature-independent method for cooling a server rack, comprising:
providing a server rack, the server rack including a plenum and housing one or more servers;
powering on the one or more servers;
determining the pressure differential between the ambient air pressure outside the server rack and the air pressure within the plenum of the server rack; and
reducing the air pressure within the plenum when pressure differential is positive.
